(19) United States
(12) Patent Application Publication
(10) Pub. No.: US 2026/0156916 A1
(43) Pub. Date: Jun. 4, 2026

(54) SIC STEP TRENCH MOSFET WITH EMBEDDED SUPPER BARRIER RECTIFIER HAVING SHORT CHANNEL

(71) Applicant: Nami MOS CO., LTD., New Taipei City (TW)

(72) Inventors: FU-YUAN HSIEH, New Taipei City (TW); LIN XU, SHANGHAI (CN)

(73) Assignee: Nami MOS CO., LTD., New Taipei City (TW)

(21) Appl. No.: 18/966,615

(22) Filed: Dec. 3, 2024

(51) Int. Cl. H10D 84/00; H10D 30/66; H10D 62/10; H10D 62/13; H10D 62/832; H10D 64/00; H10D 64/23

(52) U.S. Cl. CPC H10D 84/146; H10D 30/668; H10D 62/111; H10D 62/127; H10D 62/153; H10D 62/8325; H10D 64/117; H10D 64/2527

(57) ABSTRACT

A SiC trench power device comprises at least one SiC MOSFET and a SiC super barrier rectifier (SBR) integrated together in each unit cell having at least one-step gate trench structure for the SiC MOSFET. The at least one step gate trench comprising a first top gate trench and at least one first bottom gate trench; the first top gate trench has a trench width larger than that of the at least one first bottom gate trench; a gate electrode of the SiC MOSFET is disposed in the first top gate trench surrounded with a first insulating film on a bottom region of the first top gate trench, and surrounded with a first gate oxide on sidewalls of the top step gate trench; the first insulating film fills up the at least one first bottom gate trench having a thickness greater than that of the first gate oxide; and a Y-shape grounded P-shield region surrounds the at least one first bottom gate trench for the first gate oxide electric field reduction and short circuit capability enhancement.

### FIELD OF THE INVENTION

This invention generally relates to a unit cell structure of a semiconductor device having at least two types of gate trenches, and more particularly, to integrate a SiC step trench Metal Oxide Semiconductor Field Effect Transistor (MOSFET) or a hybrid-channel SiC step trench MOSFET having at least one step gate trench, with a SiC Super Barrier Rectifier (SBR) as a MOS-Channel diode (MCD) into the unit cell to achieve a lower on-resistance, a less switching loss and a higher short circuit capability, and further improve safe operating area.

### BACKGROUND OF THE INVENTION

Because of their faster switching speed, higher temperature operation, and lower switching loss, SiC MOSFETs are very promising to replace Si super junction MOSFETs, and Si insulated gate bipolar transistors (IGBTs). However, a parasitic PIN body diode of the SiC MOSFET has a relatively higher turn-on voltage (˜3 V) than its Si MOSFET counterpart (˜0.7 V), owing to the wide band gap properties, which deteriorates reverse recovery characteristics. As a result, an external Schottky barrier diode (SBD) is normally used in power modules to inactivate the parasitic PIN diode. However, it was found that a parasitic inductance between the MOSFET and the external SBD has a great effect on the conduction power loss.

Various integrated devices are suggested and demonstrated to improve the characteristics of the parasitic PIN body diode in the SiC MOSFET. Among them, integrating with an SBD or a Junction barrier diode (JBSD) is widely adopted. However, a high-temperature reverse leakage current of the SBD is much larger than that of the parasitic PIN diode.

Therefore, there is still a need in the art of the SiC MOSFET design and fabrication, to provide a novel cell structure, device configuration and manufacturing process that making an SGT MOSFET have a lower on-resistance and a lower switching loss.

### SUMMARY OF THE INVENTION

The present invention provides a SiC step trench MOSFET integrated with a super barrier rectifier (SBR) as a MOS-Channel diode having a short channel for reducing the switching loss. The integrated SBR creates a low potential barrier for the majority carrier in the MOS channel, which is adjustable by the gate oxide thickness, the P body doping concentration and the channel length. The SBR has a lower forward voltage Vf and a lower reverse leakage current Ir than the Schottky Barrier rectifier. Moreover, the SBR has a better and reliable performance at elevated temperature than the SBD and JSBD.

The present invention discloses a SiC power device comprising a SiC step trench MOSFET (STMOSFET) and a SiC SBR disposed in each unit cell having at least two types of gate trenches comprising: a first type gate trench for the SiC STMOSFET and a second type gate trench for the SiC SBR; The first type gate trench having a first top gate trench and at least one first bottom gate trench for the formation of a first gate electrode and a first grounded P-shield (PS) region for the gate oxide electric-field reduction, wherein the first gate electrode is disposed into the first top gate trench having a first thick oxide layer as a first insulating film on a bottom region of the first top gate trench, and the first grounded PS region is formed surrounding the at least one first bottom gate trench filled up with the first thick oxide layer, connecting with a first body region through the at least one grounded P (GP) region adjoining with a portion of sidewalls of the first type gate trench, and shorted with a source metal; The first grounded PS region having a Y-shape structure with multiple sub-PS regions forms a saturation current pitching (SCP) region with a second grounded PS region below the first body region for the short circuit capability enhancement; A second gate electrode of the SiC SBR disposed into the second type gate trench having a second thick oxide layer as a second insulating film on a bottom region of the second type gate trench; A first channel region of the SiC STMOSFET formed in a first body region along the at least one trench sidewall of the first type gate trench, and a second channel region of the SiC SBR formed in a second body region along sidewalls of the second type gate trench; the SiC STMOSFET has a first gate oxide, and the SiC SBR has a second gate oxide with an oxide thickness thinner than that of the first gate oxide; and the SiC SBR has a channel length shorter than that of the SiC STMOSFET.

According to another aspect, the invention features a SiC power device further comprising a first gate electrode disposed in an upper portion of the first top gate trench, and a shielded gate electrode disposed below the first gate electrode in the first top gate trench and isolated from each other by an inter-poly oxide (IPO) layer.

According to another aspect, the invention features a SiC power device further comprising a super junction (SJ) structure comprising a P column (PC) region of a second conductivity type. At least two sidewall P-shield (SPS) regions of a second conductivity type facing each other with a doping concentration higher than that of the PC region, adjoining the PC region, and a Junction Field Effect Transistor (JFET) region of a first conductivity type formed between the at least two SPS regions with a doping concentration higher than that of the epitaxial layer.

According to another aspect, the invention features a SiC power device further comprising a second SiC MOSFET without having the step gate trench structure to form a hybrid-channel MOSFET (HCMOSFET) with the first SiC MOSFET in the unit cell of the SiC power device for the specific on-resistance reduction, wherein the hybrid-channel MOSFET has two different threshold voltages formed by an additional short channel implantation in a channel region of the second SiC MOSFET to further improve the positive temperature coefficient for reliability assurance operated at high temperatures.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1A is a top view of a preferred embodiment for a trench semiconductor power device with stripe cells layout according to the present invention.

FIG. 1B is a cross-sectional view showing a preferred A1-A1′ cross section of FIG. 1A comprising a SiC MOSFET and a SiC SBR integrated in each unit cell wherein the first type gate trench of the SiC MOSFET has a one-step gate trench structure according to the present invention.

FIG. 1C is a cross-sectional view showing a preferred B1-B1′ cross section of FIG. 1A comprising a SiC MOSFET and a SiC SBR integrated in each unit cell with GP regions formed along sidewalls of the first type gate trench according to the present invention.

FIG. 2A is a top view of another preferred embodiment for a trench semiconductor power device with stripe cells layout according to the present invention.

FIG. 2B is a cross-sectional view showing a preferred A2-A2′ cross section of FIG. 2A comprising a SiC MOSFET and a SiC SBR integrated in each unit cell with GP regions formed along a second trench sidewall of the first type gate trench according to the present invention.

FIG. 2C is a cross-sectional view showing another preferred A2-A2′ cross section of FIG. 2A comprising a SiC MOSFET and a SiC SBR integrated in each unit cell wherein the second type gate trench of the SiC SBR has a one-step gate trench structure according to the present invention.

FIG. 2D is a cross-sectional view showing another preferred A2-A2′ cross section of FIG. 2A comprising a SiC MOSFET and a SiC SBR integrated in each unit cell with a L-Shape P-shield (LPS) region surrounding a sidewall and beneath a portion of a bottom region of the second type gate trench according to the present invention.

FIG. 2E is a cross-sectional view showing another preferred A2-A2′ cross section of FIG. 2A comprising a SiC MOSFET and a SiC SBR integrated in each unit cell with an N type buffer source (nb) region below the first and second source regions according to the present invention.

FIG. 2F is a cross-sectional view showing another preferred SiC power device embodiment comprising a SiC MOSFET and a SiC SBR integrated in each unit cell with saturation current pitching off (psc) regions according to the present invention.

FIG. 3 is a cross-sectional view showing another preferred A1-A1′ cross section of FIG. 1A comprising a SiC MOSFET and a SiC SBR integrated in each unit cell wherein the first type gate trench of the SiC MOSFET has a two-step gate trench structure according to the present invention.

FIG. 4A is a top view of another preferred embodiment for a trench semiconductor power device with stripe cells layout for a SiC hybrid-channel MOSFET integrated with a SiC SBR according to the present invention.

FIG. 4B is a cross-sectional view showing a preferred A3-A3′ cross section of FIG. 4A comprising a second SiC MOSFET forming the hybrid-channel MOSFET with the first SiC MOSFET in each unit cell according to the present invention.

FIG. 5 is a cross-sectional view showing another preferred A1-A1′ cross section of FIG. 1A comprising a SiC MOSFET and a SiC SBR integrated in each unit cell with a shielded gate electrode disposed below the first gate electrode in the first type gate trench of the SiC MOSFET according to the present invention.

FIG. 6A is a cross-sectional view showing another preferred A1-A1′ cross section of FIG. 1A comprising a SiC MOSFET and a SiC SBR integrated in each unit cell with P column (PC) regions adjoining bottom surfaces of the p1 regions above the N+ substrate according to the present invention.

FIG. 6B is a cross-sectional view showing another preferred A1-A1′ cross section of FIG. 1A comprising a SiC MOSFET and a SiC SBR integrated in each unit cell with a Junction Field Effect Transistor (JFET) region formed between two adjacent SPS regions according to the present invention.

FIG. 7A is a cross-sectional view showing another preferred A1-A1′ cross section of FIG. 1A representing an IGBT with a P+ substrate according to the present invention.

FIG. 7B is a cross-sectional view showing another preferred A1-A1′ cross section of FIG. 1A representing an IGBT with a plurality of alternating P+ and N+ regions in the P+ substrate according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

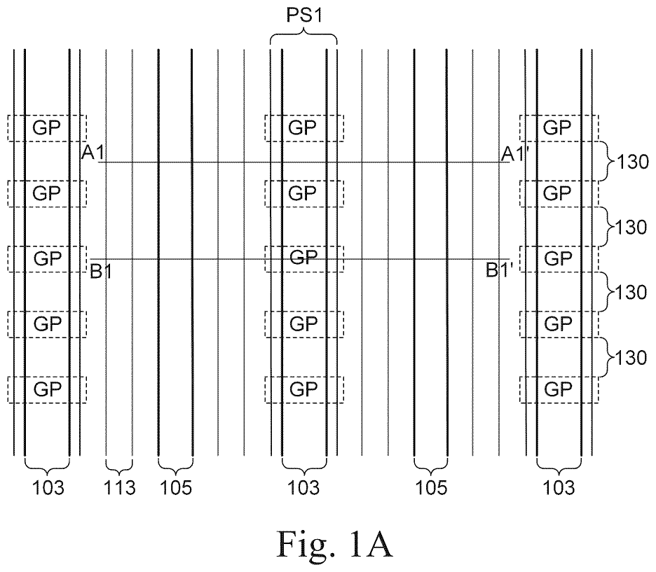

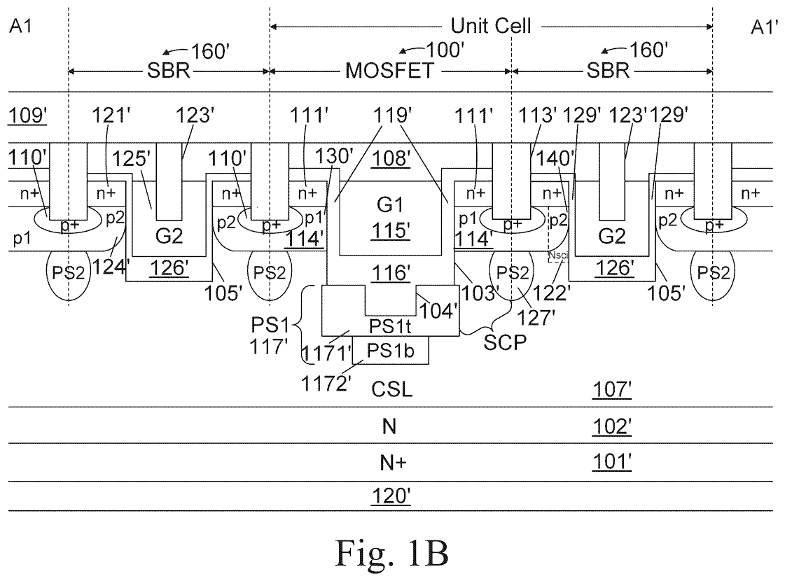

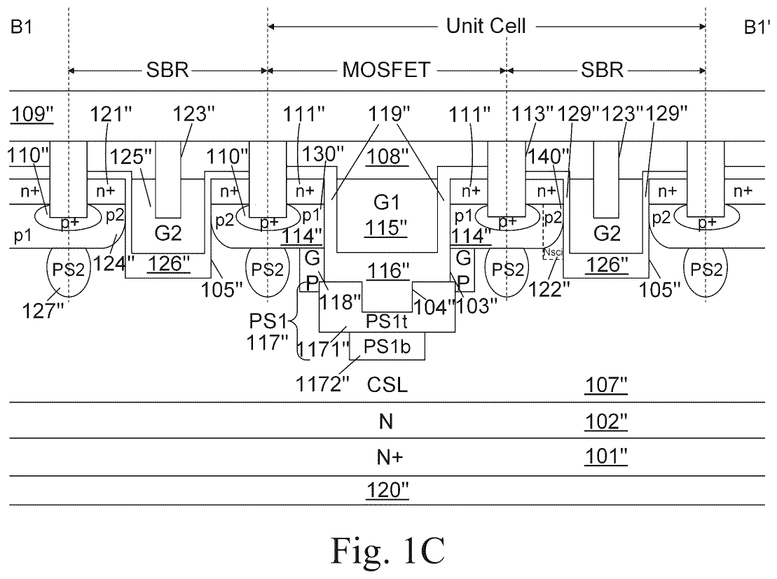

Please refer to FIG. 1A for a top view of a SiC power device comprising a first type gate trench (GT1) 103 of a SiC MOSFET and a second type gate trench (GT2) 105 of a SiC SBR disposed in each unit cell with stripe cells layout, wherein the GT1 103 is surrounded by a first P-shield (PS1, as illustrated) region, and trenched source contacts 113 are disposed between the GT1 103 and the GT2 105. According to this invention, the PS1 region is grounded to a source metal through the grounded P (GP, as illustrated) regions and the trenched source contacts 113, wherein the GP regions surround a portion of sidewalls of the GT1 103, a first channel region 130 is formed along sidewalls of the GT1 103 between the two GP regions, and the GP region and the first channel region 130 are formed alternately along sidewalls of the GT1 103.

Please refer to FIG. 1B for a preferred embodiment of A1-A1′ cross-sectional view of FIG. 1A wherein an N-channel SiC step trench MOSFET 100′ and a SiC SBR 160′ are integrated in each unit cell having a double gate trench (DGT) structure which is formed on an N+ substrate 101′ with a less doped N type epitaxial layer 102′ extending thereon, wherein the N+ substrate 101′ is coated with a back metal 120′ on rear side as a drain metal. Inside the N type epitaxial layer 102′, a plurality of gate trenches having a first type gate trenches for the SiC step trench MOSFET and a second type gate trenches for the SiC SBR are formed vertically downward from a top surface of the N type epitaxial layer 102′ and not reaching the common interface between the N type epitaxial layer 102′ and the N+ substrate 101′. The first type gate trenches have a one-step gate trench structure comprising a first top gate trench 103′ and a first bottom gate trench 104′, wherein the first top gate trench 103′ is above the first bottom gate trench 104′ with a gate width wider than that of the first bottom gate trench 104′. A first gate electrode (G1, as illustrated) 115′ of the SiC MOSFET 100′ is disposed in the first top gate trench 103′ and surrounded with a thick bottom oxide as a first insulating film 116′ on a bottom region of the first top gate trenches 103′, and surrounded with a first gate oxide (GOX1) 119′ on sidewalls of the first top gate trenches 103′, wherein the first insulating film 116′ has a greater thickness than the GOX1 119′. The first bottom gate trenches 104′ are filled up with the first insulating film 116′. While a second gate electrode (G2, as illustrated) 125′ of the SiC SBR 160′ is formed inside each of the second type gate trenches 105′, and surrounded with a second insulating film 126′ on a bottom region of the second type gate trenches 105′, and surrounded with a second gate oxide (GOX2) 129′ on sidewalls of the second type gate trenches 105′, wherein the GOX2 129′ has a thickness less than that of the GOX1 119′ and the second insulating film 126′, and the second insulating film 126′ has a thickness less than that of the first insulating film 116′. In the SiC MOSFET 100′, a first body (p1, as illustrated) region 114′ having a first n+ source region 111′ thereon is extending in an upper portion of the N type epitaxial layer 102′ and surrounding the first gate electrodes 115′ padded by the GOX1 119′, wherein a first channel region 130′ is formed in the p1 region 114′ along a portion of sidewalls of the first top gate trench 103′; while in the SBR 160′, a second body (p2, as illustrated) region 124′ having a second n+ source region 121′ thereon is extending in an upper portion of the N type epitaxial layer 102′ and surrounding the second gate electrodes 125′ padded by the GOX2 129′, wherein the p2 region 124′ has a doping concentration lower than that of the p1 region 114′, and a second channel region 140′ is formed in the p2 region 124′ along a portion of sidewalls of the second type gate trench 105′ with a channel length shorter than that of the first channel region 130′, and a short channel implant (Nsci, as illustrated) region 122′ is formed surrounding the second channel region 140′ along sidewalls of the second type gate trench 105′ by Nitrogen or Phosphorus angle implantation with a doping concentration higher than that of the N type epitaxial layer 102′. Moreover, an N type current spreading layer (CSL, as illustrated) region 107′ is formed below the first type gate trench with a doping concentration higher than that of the N type epitaxial layer 102′, and a first P-shield (PS1, as illustrated) region 117′ with a Y-shape structure for the gate oxide electric-field reduction is formed surrounding the first bottom gate trench 104′ comprising two sub-PS regions including a first top PS (PS1t, as illustrated) region 1171′ and a first bottom PS (PS1b, as illustrated) region 1172′, wherein the PS1b region 1172′ is below the PS1t region 1171′ with a lower doping concentration than the PS1t region 1171′, and a second P-shield (PS2, as illustrated) region 127′ is formed adjoining a lower surface of the p1 region 114′, forming a saturation current pitching (SCP, as illustrated) region with the PS1 region 117′ for the short circuit capability enhancement. An interlayer dielectric film 108′ is stacked on the epitaxial layer 102′, and a source metal 109′ is formed onto the interlayer dielectric film 108′. The p1 and p2 regions 114′ and 124′, the first and second n+ source regions 111′ and 121′, and the G2 125′ are shorted to the source metal 109′ through a plurality of trenched source contacts 113′ and 123′ filled with contact metal plugs and metal barriers and surrounded by p+ heavily doped regions 110′ around bottoms underneath the first and second n+ source regions 111′ and 121′.

Please refer to FIG. 1C for a preferred B1-B1′ cross-sectional view of FIG. 1A. The FIG. 1C has a similar structure to FIG. 1B, except that the FIG. 1C further comprises grounded P (GP, as illustrated) regions 118″ formed along a portion of sidewalls of the first type gate trench 103″ to ground the PS1 region 117″ to a source metal 109″ through the p1 region 114″ and the source contact 113″.

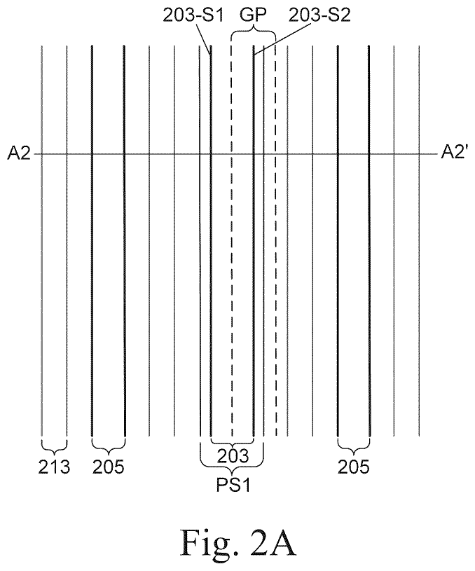

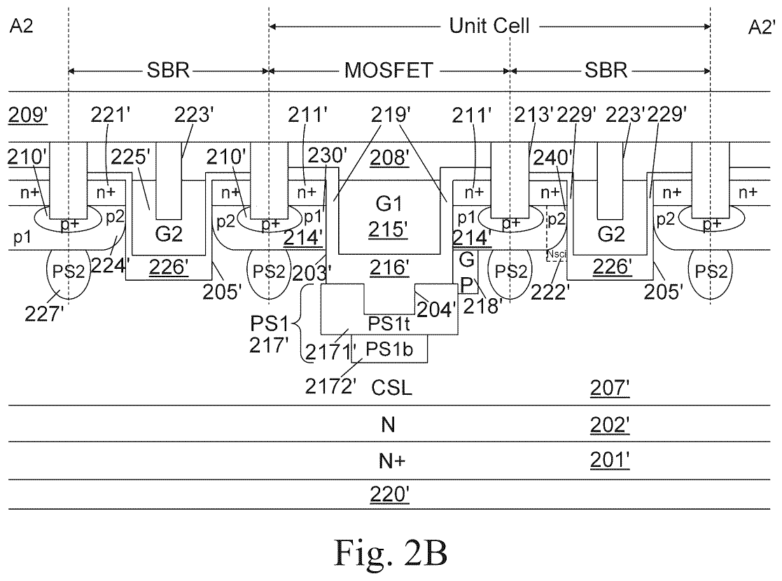

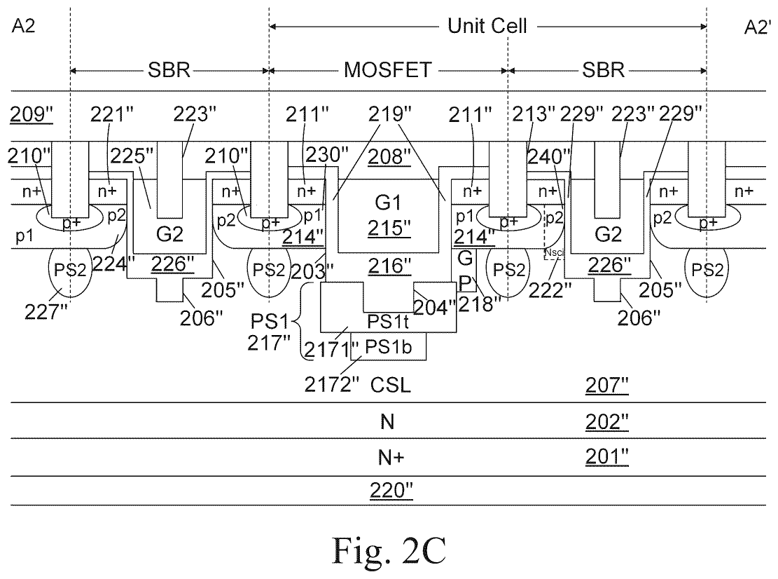

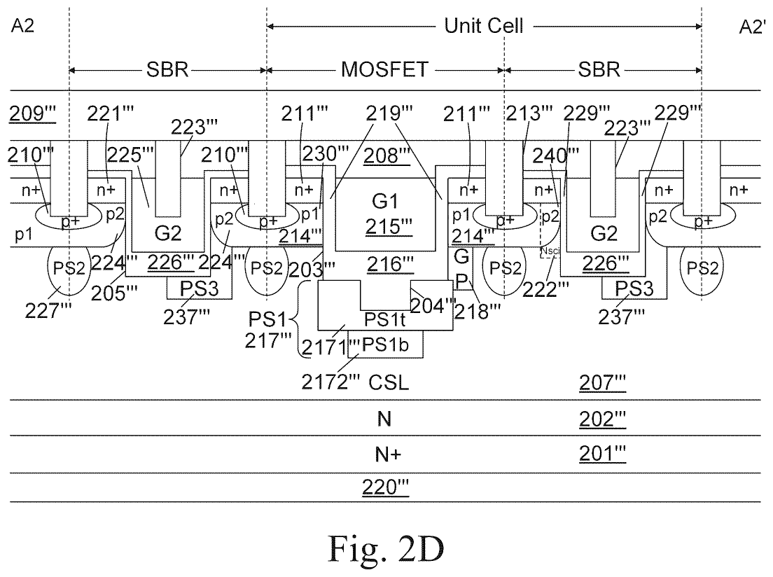

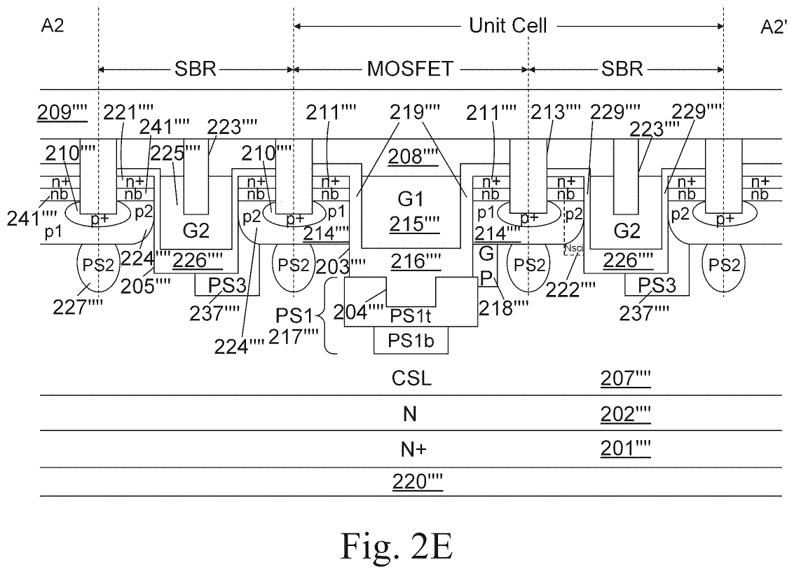

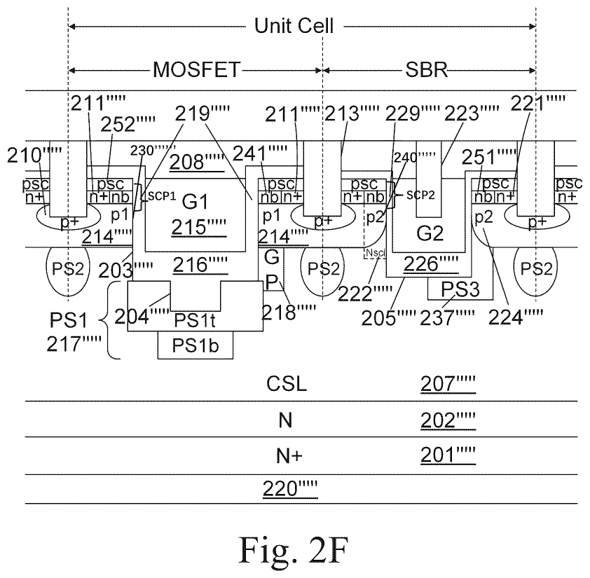

Please refer to FIG. 2A for another top view of a SiC power device comprising a SiC gate trench (GT1) 203 and a SiC SBR trench (GT2) 205 disposed in each unit cell with stripe cells layout. The SiC power device has a similar structure to FIG. 1A, except that the channel region in the present invention with a stripe shape is formed along a first sidewall 203-S1 of the GT1 203 while the GP region is formed along a second sidewall 203-S2 of the GT1 203.

Please refer to FIG. 2B for a preferred A2-A2′ cross-sectional view of FIG. 2A. The FIG. 2B has a similar structure to FIG. 1B, except that the present invention further comprises a grounded P (GP, as illustrated) region 218′ formed along a trench sidewall of the GT1 203′ to ground the PS1 region 217′ to a source metal 209′ through the p1 region 214′ and the source contact 213′.

Please refer to FIG. 2C for another preferred A2-A2′ cross-sectional view of FIG. 2A with a new and improved device structure. The SiC power device has a similar structure to FIG. 2B, except that the second type gate trench of the SiC SBR in the present invention has a one-step gate trench structure comprising a second top gate trench 205″ and a second bottom gate trench 206″, wherein the second top gate trench 205′ is above the second bottom gate trench 206″ with a gate width larger than that of the second bottom gate trench 206″ and the second bottom gate trench 206″ is filled up with the second insulating film 226″.

Please refer to FIG. 2D for another preferred A2-A2′ cross-sectional view of FIG. 2A with a new and improved device structure. The SiC power device has a similar structure to FIG. 2B, except that the present invention further comprises a third P-shield (PS3, as illustrated) region 237″′ of a second conductivity type with a L-shape structure surrounding a sidewall and beneath a portion of a bottom region of the second type gate trench 205″′, and connecting with the p2 region 224″′ for a second gate oxide electric field reduction.

Please refer to FIG. 2E for another preferred A2-A2′ cross-sectional view of FIG. 2A with a new and improved device structure. The SiC power device has a similar structure to FIG. 2D, except that the present invention further comprises an N type buffer source (nb, as illustrated) region 241″″ below the first and second source regions 211″″ and 221″″ with a doping concentration lower than that of the first and second source regions 211″″ and 221″″.

Please refer to FIG. 2F for another preferred embodiment of a SiC power device with a new and improved device structure. The SiC power device has a similar structure to FIG. 2D, except that the present invention further comprises a first N type buffer source region 241″″′ formed in a side of the first source region 211″″′ adjacent to the first channel region 230″″′ with a doping concentration lower that of the first source region 211″″′ and a second N type buffer source region 251″″′ formed in a side of the second source region 221″″′ adjacent to the second channel region 240″″′ with a doping concentration lower that of the first source region 211″″′, and furthermore, a heavily doped P type region (psc, as illustrated) 252″″′ for formation of a first and a second saturation current pitching (SCP1 and SCP2 regions, as illustrated) is disposed on a top of the first and second source regions 211″″′ and 221″″′ and the first and second buffer source regions 241″″′ and 251″″′, and is shorted to the source metal 209″″′ through trenched source contacts 213″″′, wherein the SCP1 region is formed between the psc region 252″″′ and the first body region 214″″′ while the SCP2 region formed between the psc region 252″″′ and the second body region 224″″′.

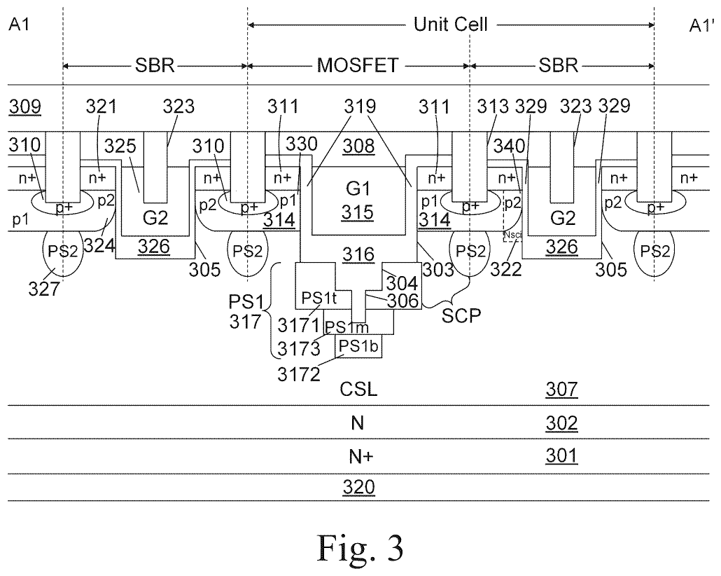

Please refer to FIG. 3 for another preferred A1-A1′ cross-sectional view of FIG. 1A with a new and improved device structure. The SiC power device has a similar structure to FIG. 1B, except that the first type gate trench of the SiC MOSFET in the present invention has a two-step gate trench structure including a first top gate trench 303 with a width Wt, a first middle gate trench 304 below the first top gate trench 303 with a width Wm, and a first bottom gate trench 306 below the middle gate trench 304 with a width Wb, wherein the relationship among the widths is Wt>Wm>Wb. Moreover, the first middle and the first bottom gate trenches 304 and 306 are filled up with the first insulating film 316 and surrounded with the first PS (PS1, as illustrated) region 317, and the PS1 region having a Y-shape structure comprises three sub-PS regions including a first top PS (PS1t, as illustrated) region 3171, a first middle PS ((PS1m, as illustrated) 3173 below the PS1t region 3171 and a first bottom PS (PS1b, as illustrated) region 3172 below the PS1m region 3173, wherein the PS1b region 3172 has a doping concentration lower than that of the PS1m region 3173, and the PS1m region 3173 has a doping concentration lower than that of the PS1t region 3171.

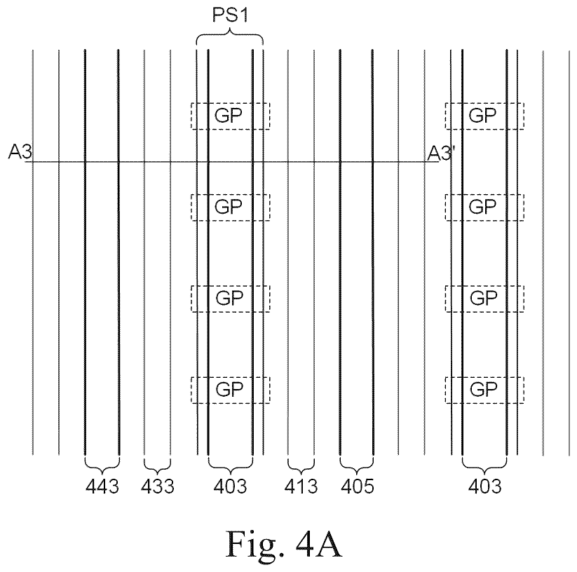

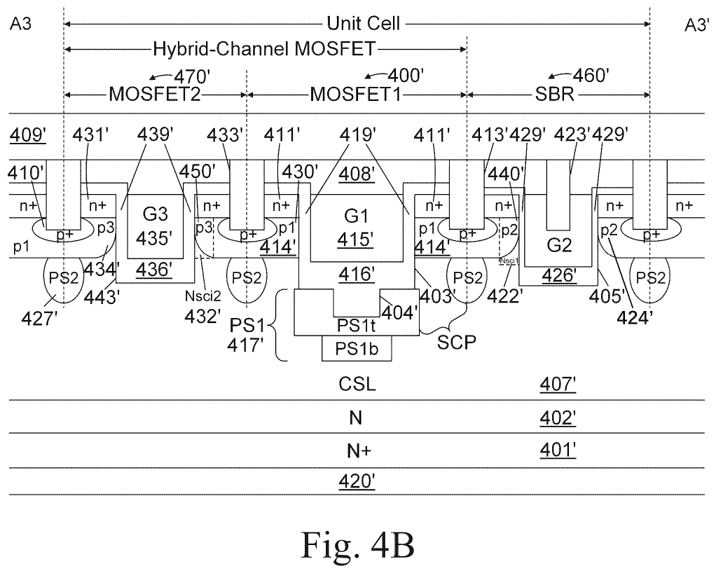

Please refer to FIG. 4A for another top view of a SiC power device comprising a first type gate trench (GT1) 403 for a first SiC MOSFET, a second type gate trench (GT2) 405 for a SiC SBR and a third type gate trench 443 for a second SiC MOSFET disposed in each unit cell with stripe cells layout. The SiC power device has a similar structure to FIG. 1A, except that the present invention further comprises a third type gate trench 443 in each unit cell.

Please refer to FIG. 4B for a preferred A3-A3′ cross-sectional view of FIG. 4A wherein a first SiC MOSFET (MOSFET1, as illustrated) 400′, a second SiC MOSFET (MOSFET2, as illustrated) 470′ and a SiC SBR 460′ are integrated in each unit cell. The SiC power device has a similar structure to FIG. 1B, except that the present invention further comprises the SiC MOSFET2 470′ forming a hybrid-channel MOSFET with the SiC MOSFET1 400′ in the cell unit of SiC power device. In the present invention, a third type gate trench 443′ of the second SiC MOSFET2 470′ is formed vertically downward from a top surface of the N type epitaxial layer 402′ and not reaching the common interface between the N type epitaxial layer 402′ and the N+ substrate 401′. A third gate electrode (G3, as illustrated) 435′ of the SiC MOSFET2 470′ is disposed in the third type gate trench 443′ and surrounded with a thick bottom oxide as a third insulating film 436′ on a bottom region of the third type gate trenches 443′, and surrounded with a third gate oxide (GOX3) 439′ on sidewalls of the third type gate trenches 443′, wherein the third insulating film 436′ has a greater thickness than the GOX3 439′. Moreover, a third p body (p3, as illustrated) region 434′ having a third n+ source region 431′ thereon is formed in an upper portion of the N type epitaxial layer 402′ and surrounds the G3 435′ padded by the GOX3 439′ with a doping concentration lower than that of the p1 regions 414′, wherein the p3 regions 434′ and the third source regions 431′ are shorted to the source metal 409′ through the trenched source contacts 433′. A third channel region 450′ of the second SiC MOSFET2 470′ is formed in the p3 region 434′ along trench sidewalls of the third type gate trench 443′, and a second short channel implant (Nsci2, as illustrated) region 432′ of a first conductivity type surrounds the third channel region 450′.

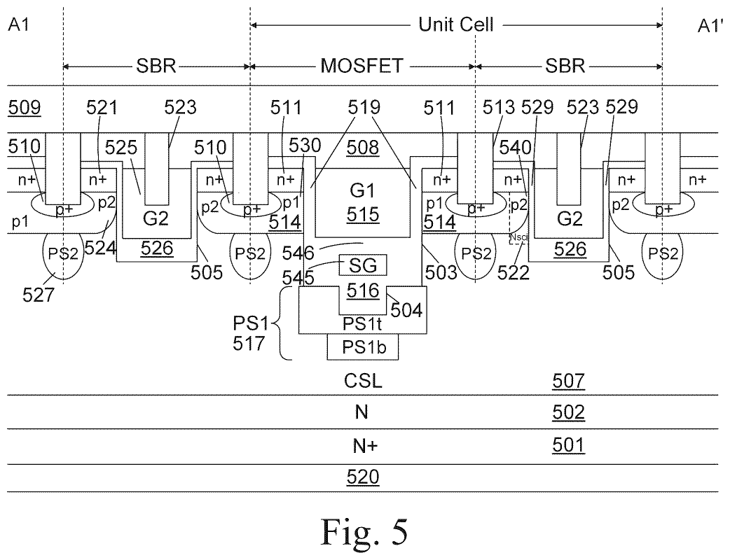

Please refer to FIG. 5 for another preferred A1-A1′ cross-sectional view of FIG. 1A with a new and improved device structure. The SiC power device has a similar structure to FIG. 1B, except for the different shielded gate structure in the first top gate trench 503 of the first type gate trenches. In the present structure, a shielded gate electrode (SG, as illustrated) 545 is disposed in a lower portion of the first top gate trench below a first gate electrode (G1, as illustrated) 515 in an upper portion of the first top gate trench, and the first gate electrode 515 is laterally isolated from the adjacent epitaxial layer by a first gate oxide (GOX1) 519 on the gate trench sidewall, and the SG 545 is vertically isolated from the epitaxial layer by an insulating layer 516 on a bottom region of the first top gate trench, wherein the insulating layer 516 has a thicker thickness than the GOX1 519. Meanwhile, the SG 545 and the G1 515 are insulated from each other by another insulating film 546 as an inter-poly oxide (IPO) layer.

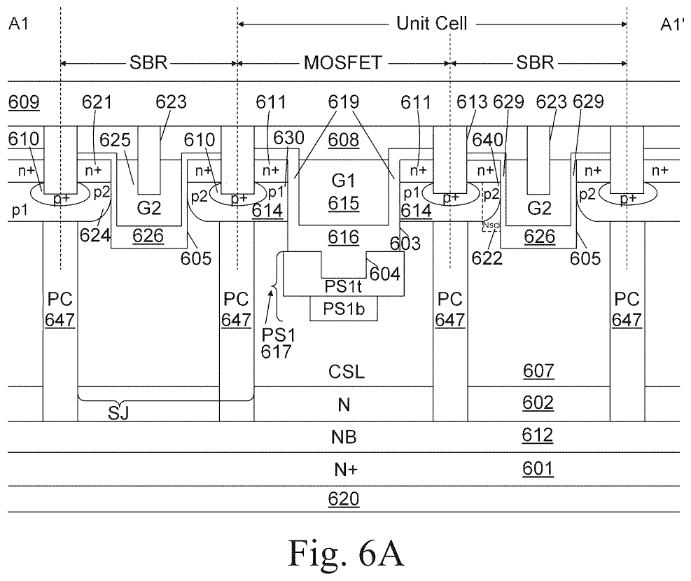

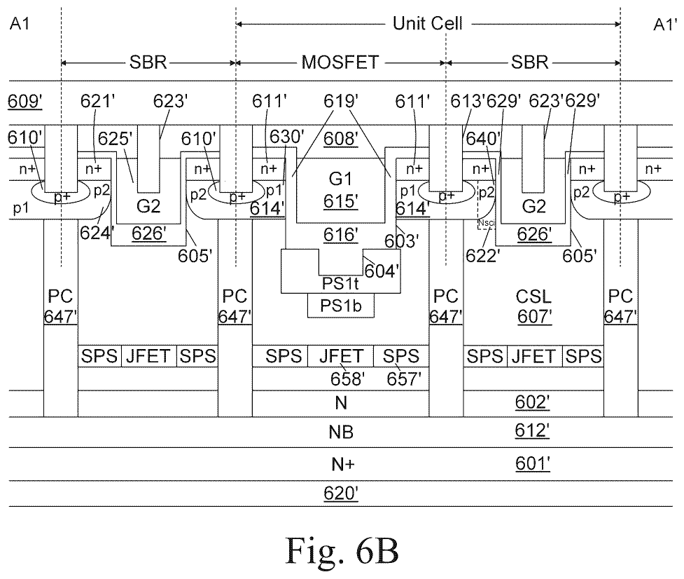

Please refer to FIG. 6A for another preferred A1-A1′ cross-sectional view of FIG. 1A with a new and improved device structure. The SiC power device has a similar structure to FIG. 1B, except that the PS2 regions 127′ in FIG. 1B don't exist in FIG. 6A, and the present invention further comprises an N buffer layer (NB, as illustrated) 612 with a resistivity Rb sandwiched between the N+ substrate 601 and the N type epitaxial layer 602, and the N type epitaxial layer 602 comprises a single epitaxial layer having a uniform doping concentration with a resistivity R, wherein R<Rb. Besides, P column (PC, as illustrated) regions 647 of a second conductivity type are introduced into the N epitaxial layer 602 to form a SJ region, comprising a plurality of alternating P regions 647 and N regions 602. The PC regions 647 are formed adjoining bottom surfaces of the p1 regions 614 and touch to the bottom surface of the N type epitaxial layer 602 by multiple epi method or by opening a deep trench filled up with an epitaxial layer of the second conductivity type method.

Please refer to FIG. 6B for another preferred A1-A1′ cross-sectional view of FIG. 1A with a new and improved device structure. The SiC power device has a similar structure to FIG. 6A, except that the present invention further comprises two sidewall P-shield (SPS, as illustrated) regions 657′ of a second conductivity type facing each other horizontally adjoining the P column (PC, as illustrated) regions 647′ and being spaced apart from the p1 regions 614′ with a doping concentration higher than that of the PC regions 647′, and a Junction Field Effect Transistor (JFET, as illustrated) region 658′ of a first conductivity type is formed between the two SPS regions 657′ with a doping concentration higher than that of the N type epitaxial layer 602′.

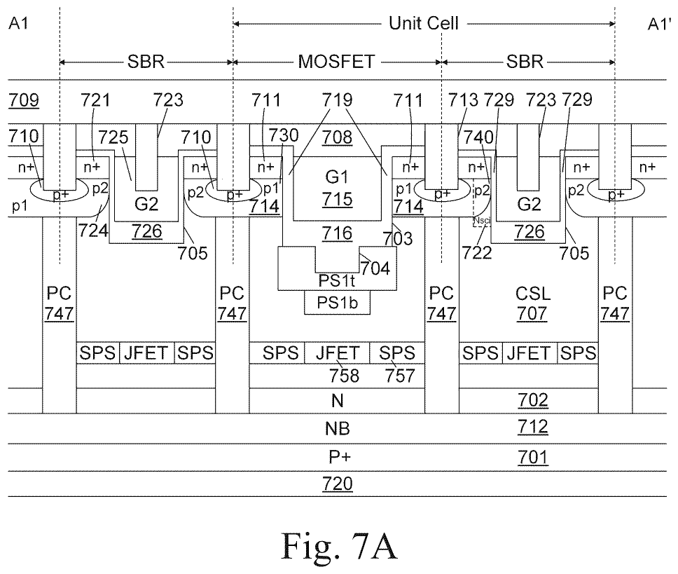

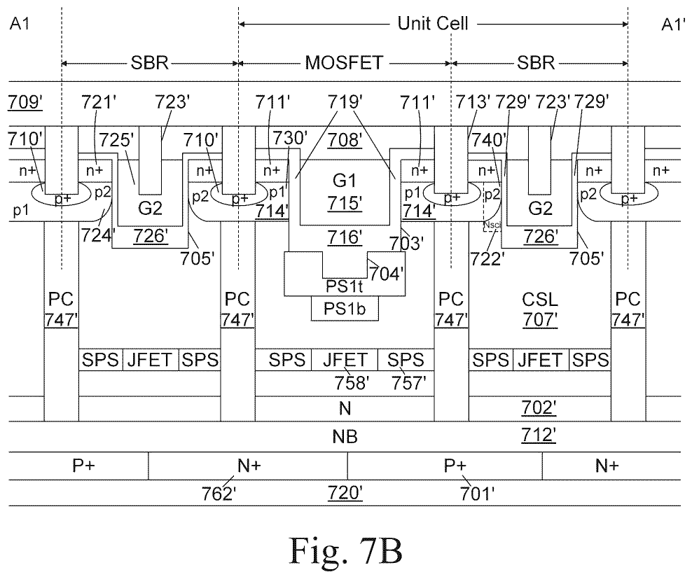

Please refer to FIG. 7A for another preferred A1-A1′ cross-sectional view of FIG. 1A with a new and improved device structure. The SiC power device has a similar structure to FIG. 6B, except for the different substrate. In this invention, the SiC power device is formed on a P+ substrate 701, and the N buffer layer (NB, as illustrated) 712 sandwiched between the P+ substrate 701 and the PC regions 747 has a resistivity Rb lower than a resistivity R of the N type epitaxial layer 702.

Please refer to FIG. 7B for another preferred A1-A1′ cross-sectional view of FIG. 1A with a new and improved device structure. The SiC power device has a similar structure to FIG. 7A, except that the SiC power device in FIG. 7B further comprises a plurality of heavily doped N+ regions 762′ in the P+ substrate 701′ to form a plurality of alternating P+ and N+ regions in the substrate.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A SiC power device comprising a first SiC MOSFET and a SiC super barrier rectifier (SBR) disposed in each unit cell having at least two types of gate trenches comprising:
an epitaxial layer of a first conductivity type grown on a substrate;
said at least two types of gate trenches having a first type gate trench for said first SiC MOSFET and a second type gate trench for said SiC SBR;
said first SiC MOSFET further comprising:
said first type gate trench having at least one-step gate trench structure;
said at least one-step gate trench structure having a first top gate trench and at least one first bottom gate trench; said first top gate trench is above said at least one first bottom gate trench and has a trench width larger than that of said at least one first bottom gate trench;
a first gate electrode disposed in said first top gate trench surrounded with a first insulating film on a bottom region of said first top gate trench, and with a first gate oxide on sidewalls of said first top gate trench; said first insulating film having a thickness greater than that of said first gate oxide;
a first body region of a second conductivity type having a first source region of said first conductivity type thereon;
a first channel region of said first SiC MOSFET formed in said first body region along at least one sidewall of said first top gate trench connecting to said first source region;
a first P-shield region (PS) of said second conductivity type for the gate oxide electric-field reduction surrounding said at least one first bottom gate trench filled up with said first insulating film;
said first PS region comprising at least two sub-PS regions including a first top PS region and a first bottom PS region, wherein said first bottom PS region is below said first top PS region with a doping concentration lower than that of said top PS region; and
at least one grounded P (GP) region of said second conductivity type surrounding a portion of sidewalls of said first type gate trench connecting with said first body region and said first PS region. said SiC SBR further comprising:
a second type gate trench formed in said epitaxial layer;
a second gate electrode disposed in said second type gate trench surrounded with a second insulating film on a bottom region of said second type gate trench, and with a second gate oxide on sidewalls of said second type gate trench; and
said second gate oxide has a thickness less than that of said second insulating film;
a second body region of said second conductivity type having a second source region of said first conductivity type thereon;
said second body region has a doping concentration lower than that of said first body region;
a second channel region of said SiC SBR formed in said second body region along at least one sidewall of said second type gate trench connecting to said second source region;
said first and second body regions, said first and second source regions, and said second gate electrode being shorted to a source metal through source contacts.

2. The SiC power device of claim 1, wherein said at least one first bottom gate trench comprising a single first bottom gate trench surrounded by said first PS region having a Y-shape structure.

3. The SiC power device of claim 1, wherein said at least one first bottom gate trench comprising multiple first bottom gate trenches surrounded by said first PS region having a Y-shape structure.

4. The SiC power device of claim 1, wherein said first type gate trench having a two-step gate trench structure;
said two-step gate trench structure having said first top gate trench with a width Wt, a first middle gate trench with a width Wm and said first bottom gate trench with a width Wb; said first top gate trench is above said middle gate trench, and said middle gate trench is above said first bottom gate trench, wherein said Wt>Wm>Wb; and
said first PS region comprising three sub-PS regions including said first top PS region, a first middle PS region and said first bottom PS region, wherein said first bottom PS region is below said first middle PS region with a doping concentration lower than that of said middle PS region and said first middle PS region is below said first top PS region with a doping concentration lower than that of said top PS region.

5. The SiC power device of claim 1, further comprising:
a second SiC MOSFET forming a hybrid-channel MOSFET with said first SiC MOSFET in said each unit cell of said SiC power device;
said second SiC MOSFET comprising:
a third type gate trench formed in said epitaxial layer;
a third gate electrode of said second SiC MOSFET disposed in said third type gate trench;
said third gate electrode surrounded with a third insulating film on a bottom region of said third type gate trench, and with a third gate oxide on sidewalls of said third type gate trench; said third insulating film having a greater thickness than said third gate oxide;
a third body region of said second conductivity type having a third source region of said first conductivity type thereon;
said third body region has a doping concentration lower than that of said first body region;
a third channel region of said second SiC MOSFET formed in said third body region along at least one sidewall of said third type gate trench connecting to said third source region; and
said third body and third source regions being shorted to said source metal.

6. The SiC power device of claim 1, further comprising a first short channel implant (SCI) region of said first conductivity type surrounding said second channel region, wherein said SCI region is formed by a Nitrogen or Phosphorus angle implantation and having a doping concentration higher than that of said epitaxial layer; said second channel region has a channel length shorter than that of said first channel region; and said second gate oxide has a oxide thickness thinner than that of said first gate oxide.

7. The SiC power device of claim 5, further comprising a second SCI region of said first conductivity type surrounding said third channel region with a channel length shorter than that of said first channel region.

8. The SiC power device of claim 1, further comprising a current spreading layer (CSL) of said first conductivity type below said first type gate trench with a doping concentration higher than that of said epitaxial layer.

9. The SiC power device of claim 1, further comprising a buffer source region of said first conductivity type below said first and second source regions with a doping concentration lower than that of said first and second source regions.

10. The SiC power device of claim 1, further comprising:
a first buffer source region of said first conductivity type formed in a side of said first source region adjacent to said first channel region with a doping concentration lower that of said first source region;
a second buffer source region of said first conductivity type formed in a side of said second source region adjacent to said second channel region with a doping concentration lower that of said second source region; and
a heavily doped P type region (Psc) of said second conductivity type disposed on top regions of said first and second source regions and said first and second buffer source regions to form a first and second saturation current pitching regions with said first body and said second body regions, respectively; and
said Psc region shorted to said source metal through said source contacts.

11. The SiC power device of claim 1, further comprising a shielded gate electrode disposed in a lower portion of said first top gate trench of said first type gate trench below said first gate electrode, and isolated from each other by an inter-poly oxide (IPO) layer.

12. The SiC power device of claim 1, wherein said GP region and said first channel region are formed alternately along sidewalls of said first type gate trench.

13. The SiC power device of claim 1, wherein said first channel region is formed along a first sidewall of said first type gate trench while said GP region is formed along a second sidewall of said first type gate trench, wherein said first sidewall is opposite to said second sidewall.

14. The SiC power device of claim 1, further comprising a second PS region of said second conductivity type adjoining a lower surface of said first body region, forming a saturation current pitching (SCP) region with said first PS region for the short circuit capability enhancement.

15. The SiC power device of claim 1, further comprising a third PS region of said second conductivity type having a L-shape structure surrounding a sidewall and beneath a portion of a bottom region of said second type gate trench, and connecting with said second body region for the second gate oxide electric field reduction.

16. The SiC power device of claim 1, further comprising a super junction (SJ) structure comprising a P column (PC) region of said second conductivity type disposed on a buffer layer of said first conductivity type with a resistivity Rb sandwiched between said substrate and said epitaxial layer, and said PC region is connected to said first and second body regions, and forms said SJ structure with said epitaxial layer.

17. The SiC power device of claim 16, wherein said substrate has said first conductivity type and said epitaxial layer comprises a single epitaxial layer having a uniform doping concentration with a resistivity R, said R<said Rb.

18. The SiC power device of claim 16, wherein said substrate has said second conductivity type and said epitaxial layer comprises a single epitaxial layer having a uniform doping concentration with a resistivity R, said R>said Rb.

19. The SiC power device of claim 18, further comprising a plurality of heavily doped regions of said first conductivity type in said substrate to form a plurality of alternating P+ and N+ regions in said substrate.

20. The SiC power device of claim 16, further comprising at least two sidewall P-shield (SPS) regions of said second conductivity type facing each other with a doping concentration higher than a doping concentration of said PC region, adjoining said PC region and being spaced apart from said first body region, and a Junction Field Effect Transistor (JFET) region of said first conductivity type formed between said at least two SPS regions with a doping concentration higher than that of said epitaxial layer.
